(19) United States
(12) Patent Application Publication
(10) Pub. No.: US 2013/0047428 A1
(43) Pub. Date: Feb. 28, 2013

(54) METHOD OF MANUFACTURING TOUCH PANEL

(71) Applicant: Seung Hyun Ra, Gyunggi-do (KR)

(72) Inventor: Seung Hyun Ra, Gyunggi-do (KR)

(73) Assignee: SAMSUNG ELECTRO-MECHANICS CO., LTD., Gyunggi-do (KR)

(21) Appl. No.: 13/284,809

(22) Filed: Oct. 28, 2011

(30) Foreign Application Priority Data
Aug. 29, 2011 (KR) 1020110086609

(51) Int. Cl. H05K 3/12

(52) U.S. Cl. 29/846

(57) ABSTRACT

Disclosed herein is a method of manufacturing a touch panel. A method of manufacturing a touch panel according to the present invention includes: patterning a transparent substrate using a stamp so that the transparent substrate has concave portions depressed therein; applying a barrier layer only to outer sides of the concave portions of the transparent substrate so that the concave portions are exposed; and forming sensing electrodes in the concave portions, the sensing electrode made of a metal.

### CROSS REFERENCE TO RELATED APPLICATION

This application claims the benefit of Korean Patent Application No. 10-2011-0086609, filed on Aug. 29, 2011, entitled “Method of Manufacturing Touch Panel”, which is hereby incorporated by reference in its entirety into this application.

### BACKGROUND OF THE INVENTION

1. Technical Field

The present invention relates to a method of manufacturing a touch panel.

2. Description of the Related Art

Alongside the growth of computers using digital technology, devices assisting computers have also been developed, and personal computers, portable transmitters and other personal information processors execute processing of text and graphics using a variety of input devices such as a keyboard and a mouse.

While the rapid advancement of the information-based society has been widening the use of computers more and more, there have been occurring the problems of it being difficult to efficiently operate products using only the keyboard and mouse as being currently responsible for the input device function. Thus, the demand for a device that is simple, has minimum malfunction, and has the capability to easily input information is increasing.

Furthermore, current techniques for input devices exceed the level of fulfilling general functions and thus are progressing towards techniques related to high reliability, durability, innovation, designing and manufacturing. To this end, a touch panel has been developed as an input device capable of inputting information such as text and graphics.

The touch panel is mounted on the display surface of an image display device such as an electronic organizer, a flat panel display including a liquid crystal display (LCD) device, a plasma display panel (PDP), an electroluminescence (El) element or the like, or a cathode ray tube (CRT), so that a user selects the information desired while viewing the image display device.

The touch panel is classifiable as a resistive type, a capacitive type, an electromagnetic type, a surface acoustic wave (SAW) type, and an infrared type. The type of touch panel selected is one that is adapted for an electronic product in consideration of not only signal amplification problems, resolution differences and the degree of difficulty of designing and manufacturing technology but also in light of optical properties, electrical properties, mechanical properties, resistance to the environment, input properties, durability and economic benefits of the touch panel. In particular, resistive and capacitive types are prevalently used in a broad range of fields currently.

Meanwhile, in the touch panel, a sensing electrode is generally formed of indium tin oxide (ITO). ITO has excellent electric conductivity, but a raw material thereof, that is, indium is a rare earth metal and is thus expensive, and besides, it is expected to run out in 10 years and therefore, supply and demand thereof will not be smooth.

For this reason, studies for forming a sensing electrode using a metal have actively progressed. The sensing electrode made of a metal has more excellent electric conductivity and more smooth supply and demand, as compared with the ITO. However, with the method of manufacturing a touch panel according to the prior art, the sensing electrode is formed by a photolithography process, of which manufacturing process is complicated and manufacturing costs are high. In addition, when the sensing electrode is formed by the photolithography process, the sensing electrode is protruded from a transparent substrate to thereby be structurally weakened.

### SUMMARY OF THE INVENTION

The present invention has been made in an effort to provide a method of manufacturing a touch panel in which concave portions are patterned in a transparent substrate and then a barrier layer is formed only on the outer sides of the concave portions to thereby form the sensing electrodes in the concave portions, whereby the manufacturing process thereof can be simplified and the manufacturing costs thereof can be reduced.

According to a preferred embodiment of the present invention, there is provided a method of manufacturing a touch panel, including: (A) patterning a transparent substrate using a stamp so that the transparent substrate has concave portions depressed therein; (B) applying a barrier layer only to the outer sides of the concave portions of the transparent substrate so that the concave portions are exposed; and (C) forming sensing electrodes in the concave portions, the sensing electrodes being made of a metal.

At step (B), the barrier layer may be applied using a printing roll.

At step (C), the sensing electrodes may be formed by a deposition process, a plating process or an inkjet printing process.

After step (C), the method may further include removing the barrier layer.

The barrier layer may be made of a thermosetting resin or a photocurable resin.

After step (B), the method may further include curing the barrier layer.

At step (C), electrode wirings may be formed in the concave portions simultaneously with forming the sensing electrodes, the electrode wirings being made of a metal and connected to the sensing electrodes.

At step (A), the stamp may be a flat type or a circular type.

At step (C), the sensing electrodes may be formed so as to be embedded in the concave portions.

### BRIEF DESCRIPTION OF THE DRAWINGS

FIGS. 1 to 6 are cross-sectional views sequentially showing the process of manufacturing a touch panel according to a preferred embodiment of the present invention;

FIG. 7 is a plan view of the touch panel according to the preferred embodiment of the present invention; and

FIGS. 8 to 10 are cross-sectional views of touch panels manufactured using the preferred embodiment of the present invention.

### DESCRIPTION OF THE PREFERRED EMBODIMENTS

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, in describing the present invention, a detailed description of related known functions or configurations will be omitted so as not to obscure the gist of the present invention.

Hereinafter, preferred embodiments of the present invention will be described in detail with reference to the accompanying drawings.

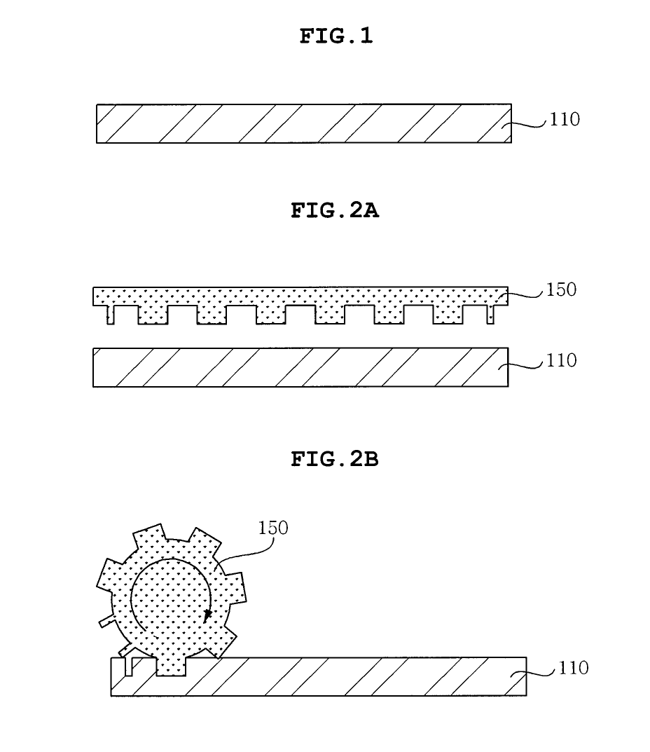

FIGS. 1 to 6 are cross-sectional views sequentially showing the process of manufacturing a touch panel according to a preferred embodiment of the present invention.

Referring to FIGS. 1 to 6, a method of manufacturing a touch panel 100 according to the present embodiment includes (A) patterning a transparent substrate 110 using a stamp 150 so that the transparent substrate 110 has concave portions 115 depressed therein; (B) applying a barrier layer 120 only to outer sides of the concave portions 115 of the transparent substrate 110 so that the concave portions 115 are exposed; and (C) forming sensing electrodes 130 in the concave portions 115, the sensing electrode being made of a metal.

First, as shown in FIG. 1, the transparent substrate 110 is prepared. Herein, the transparent substrate 110 serves to provide an area in which sensing electrodes 130 and electrode wirings 140 are formed (see FIG. 5). Therefore, the transparent substrate 110 needs to be provided with supporting force capable of supporting the sensing electrodes 130 and the electrode wirings 140 and transparency through which a user can recognize an image provided from an image display apparatus. In consideration of the supporting force and transparency, the material of the transparent substrate 110 may include polyethyleneterephthalate (PET), polycarbonate (PC), polymethylmethacrylate (PMMA), polyethylenenaphthalate (PEN), polyethersulfone (PES), cyclic olefin copolymer (COC), triacetylcellulose (TAC) film, polyvinyl alcohol (PVA) film, polyimide (PI) film, polystyrene (PS), biaxially oriented polystyrene (BOPS; containing K resin), glass or tempered glass, and so on, but is not particularly limited thereto.

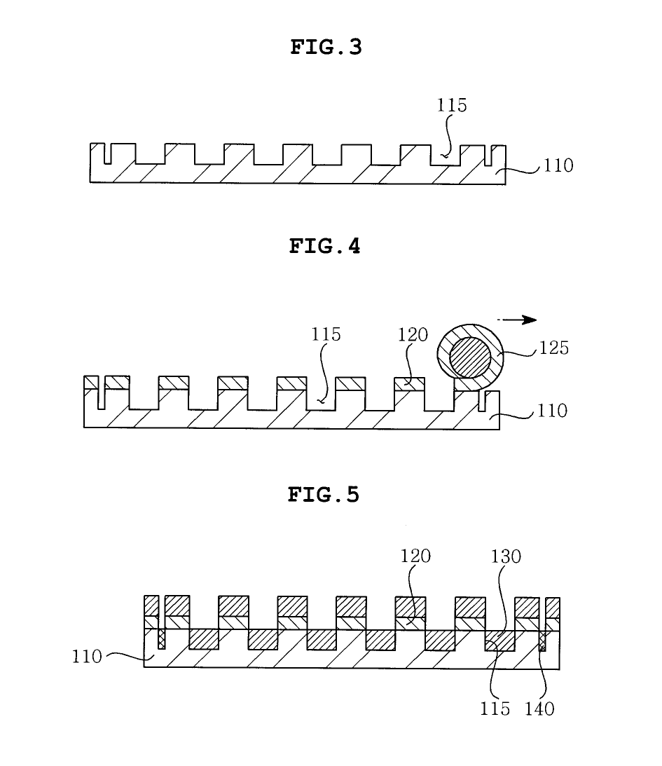

Then, as shown in FIGS. 2 and 3, the transparent substrate 110 is patterned using the stamp 150 so that the transparent substrate 110 has concave portions 115 depressed therein. Herein, the concave portions 115 are formed by depressing the transparent substrate 110 using the stamp 150 at a predetermined depth in a thickness direction. The sensing electrodes 130 and the electrode wirings 140 are to be formed in the concave portions 115 in the subsequent steps. Therefore, in consideration of the patterns of the sensing electrodes 130 and the electrode wirings 140, it is preferable that the transparent substrate 110 is patterned using the stamp 150. Herein, the type of the stamp 150 is not particularly limited, if it is processed as an embossing type, but a flat type (see FIG. 2A) or a circular type (see FIG. 2B) thereof may also be used. Among others, when the circular type stamp 150 is used, a continuous process may be performed by applying a roll to roll process thereto.

Then, as shown in FIG. 4, the barrier layer 120 is applied only to the outer sides of the concave portions 115 of the transparent substrate 110 so that the concave portions 115 are exposed. More specifically, the barrier layer 120 may be formed by an offset printing method or the like using a printing roll 125. Portions other than the concave portions 115 of the transparent substrate 110 are relatively protruded. Therefore, when the printing roll 125 is rotated from one side of the transparent substrate 110 to the other side thereof (in an arrow direction), the barrier layer 120 are transferred only on the portions rather than the concave portions 115 of the transparent substrate 110 and the concave portions 115 are exposed. Meanwhile, as the barrier layer 120, a thermosetting resin or a photocurable resin (dry film, liquid photoresist) may be used.

After the barrier layer 120 is formed using the printing roll 125, the barrier layer 120 is cured. Herein, the barrier layer 120 may be cured using heat or light (ultraviolet rays) according to a material of the barrier layer 120. More specifically, when a thermosetting resin is used as the barrier layer 120, the barrier layer 120 is cured using heat. When a photocurable resin is used as the barrier layer 120, the barrier layer 120 is cured using light (ultraviolet rays).

Then, as shown in FIG. 5, the sensing electrodes 130 are made of a metal in the concave portions 115. Herein, the sensing electrodes 130 may, for example, be formed by a deposition process using a sputtering method, an E-beam evaporation method, or the like. The sensing electrodes 130 may also be formed by a plating process, an inkjet printing process, or the like, not being limited to the deposition process. More specifically, when the sensing electrodes 130 are formed by a plating process, the sensing electrodes 130 may be formed by forming a seed layer through an electroless plating and then performing electrolytic plating on the seed layer using a lead wire. In this configuration, the sensing electrodes 130 are formed in the depressed concave portions 115 and therefore, the sensing electrodes 130 are finally formed to be embedded in the concave portions 115. As a result, a bottom surface and a side surface of the sensing electrode 130 are in contact with the concave portion 115, thereby making it possible to secure structural reliability of the sensing electrode 130.

Meanwhile, as a metal configuring the sensing electrode 130, copper (Cu), aluminum (Al), gold (Au), silver (Ag), titanium (Ti), palladium (Pd), chrome (Cr), or a combination thereof may be used. Among others, when the sensing electrode 130 is formed using copper (cu), black oxide may be performed on the surface of the sensing electrode 130. The black oxide means a process of oxidizing a surface of the sensing electrode 130 to thereby precipitate Cu₂O or CuO. The surface of the sensing electrode 130 is subjected to the black oxide, thereby making it possible to prevent light from being reflected on the sensing electrode 130 and thus to improve visibility of the touch panel 100. However, the sensing electrode 130 may be made of all metals having high electric conductivity and being easily processed, without being limited to the metal. Furthermore, since the sensing electrode 130 is made of a metal, the sensing electrode 130 may be formed in a mesh pattern in order to avoid problems of transparency of the touch panel 100 due to characteristics of an opaque metal (see FIG. 7).

In addition, the electrode wirings 140 may also be made of a metal in the concave portions 115 simultaneously with forming the sensing electrodes 130 therein. Herein, the electrode wiring 140 is connected to the sensing electrode 130. The electrode wiring 140 is formed integrally with the sensing electrode 130, thereby making it possible to simplify a manufacturing process of the touch panel 100 and to shorten a lead time. Furthermore, the electrode wiring 140 is formed simultaneously with forming the sensing electrode 130, thereby making it possible to omit a bonding process between the electrode wiring 140 and the sensing electrode 130 and thus to prevent steps or bonding defects between the sensing electrode 130 and the electrode wiring 140 from occurring.

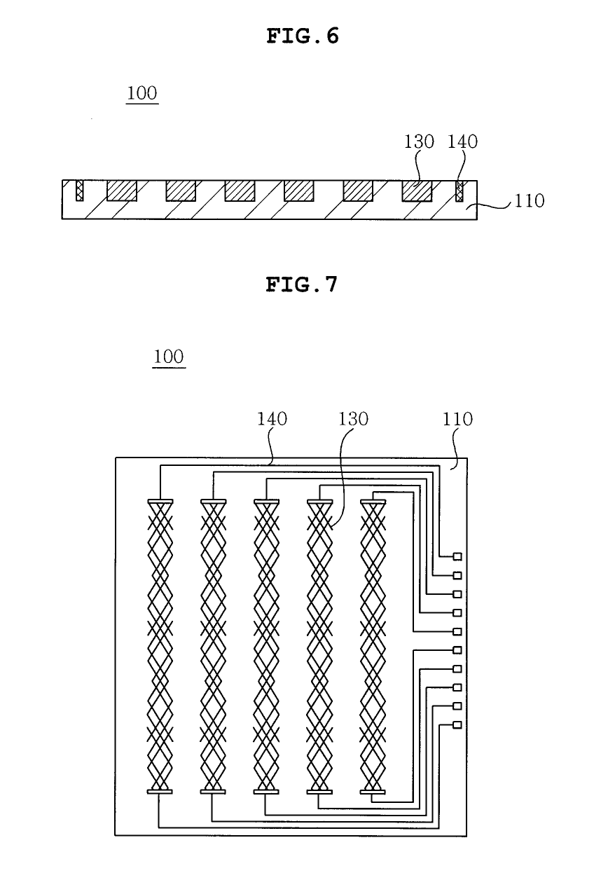

Then, as shown in FIG. 6, the barrier layer 120 is removed. The sensing electrodes 130 are formed in the aforementioned step, such that the function of the barrier layer 120 is completed. Therefore, the barrier layer 120 is removed in the present step. Herein, the barrier layer 120 may be removed using a stripper such as NaOH, KOH or the like. The barrier layer 120 is removed as described above, whereby the manufacturing of the touch panel 100 is completed.

FIG. 7 is a plan view of the touch panel according to the preferred embodiment of the present invention.

As shown in FIG. 7, the touch panel 100 according to the present invention is configured to include the transparent substrate 110, the sensing electrodes 130 and the electrode wirings 140. Herein, the sensing electrode 130 serves to generate a signal when being touched by an input unit to allow a controller to recognize touched coordinates, and the electrode wiring 140 is connected to the sensing electrode 130 to serve to receive the electrical signal from the sensing electrode 130 and transfer the received electrical signal to the controller. As described above, the touch panel 100 according to the present invention may be used as a self capacitive type touch panel or a mutual capacitive type touch panel by using the sensing electrodes 130 having a single layer structure. However, the touch panel according to the present invention is not limited thereto but may be manufactured in various types having the configurations, as described below.

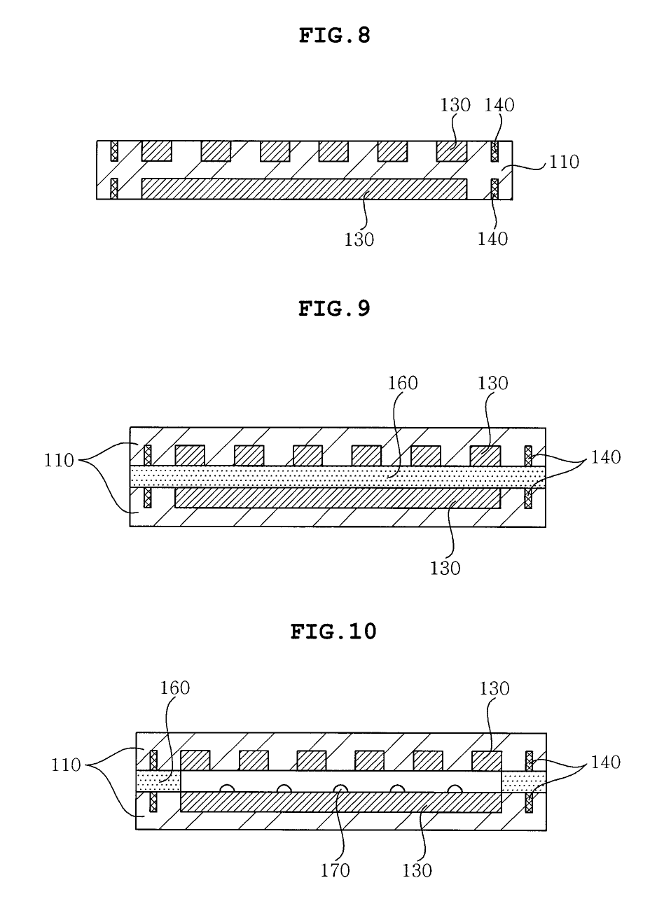

FIGS. 8 to 10 are cross-sectional views of touch panels manufactured using the preferred embodiment of the present invention.

As shown in FIGS. 8 to 10, a mutual capacitive touch panel (see FIG. 8) may be manufactured by forming the transparent electrodes 130 on both surfaces of the transparent substrate 110, respectively. In addition, as shown in FIGS. 9 and 10, a mutual capacitive type touch panel (see FIG. 9) or a resistive type touch panel (see FIG. 10) may be manufactured by preparing two transparent substrates 110 including the sensing electrodes 130 formed on one surface thereof and bonding the two transparent substrates 110 to each other using an adhesive layer 160 so that the sensing electrodes 130 face each other. Herein, in the case of the mutual capacitive type touch panel (see FIG. 9), the adhesive layer 160 is bonded to the front surface of the transparent electrode 110 so that the two facing sensing electrodes 130 are insulated from each other. Meanwhile, in the case of the resistive type touch panel (see FIG. 10), the adhesive layer 160 is bonded only to the edge of the transparent substrate 110 so that the so that the two facing sensing electrodes 130 are in contact with each other when pressure of an input unit is operated and dot spacers 170 are provided on the exposed surfaces of the sensing electrode 130, the dot spacer providing repulsive force so that the sensing electrode 130 is returned to its original position when the pressure of the input unit is removed.

According to the present invention, the sensing electrodes are formed in the concave portions by patterning the concave portions in the transparent substrate and then forming the barrier layer only on the outer sides of the concave portion, whereby the manufacturing process can be simplified and the manufacturing cost can be reduced as compared with a photolithography process.

According to the present invention, the depressed concave portions are formed in the transparent substrate using the stamp and the sensing electrodes are formed in the concave portions so that the sensing electrodes may be embedded in the concave portions, whereby the structural reliability of the sensing electrodes can be secured.

Although the preferred embodiments of the present invention have been disclosed for illustrative purposes, they are for specifically explaining the present invention and thus a method of manufacturing a touch panel according to the present invention is not limited thereto, but those skilled in the art will appreciate that various modifications, additions and substitutions are possible, without departing from the scope and spirit of the invention as disclosed in the accompanying claims. Accordingly, any and all modifications, variations or equivalent arrangements should be considered to be within the scope of the invention, and the detailed scope of the invention will be disclosed by the accompanying claims.

What is claimed is:

1. A method of manufacturing a touch panel, comprising:
patterning a transparent substrate using a stamp so that the transparent substrate has concave portions depressed therein;
applying a barrier layer only to the outer sides of the concave portions of the transparent substrate so that the concave portions are exposed; and
forming sensing electrodes in the concave portions, the sensing electrodes being made of a metal.

2. The method as set forth in claim 1, wherein the barrier layer is applied using a printing roll.

3. The method as set forth in claim 1, wherein the sensing electrodes are formed by a deposition process, a plating process or an inkjet printing process.

4. The method as set forth in claim 1, further comprising, removing the barrier layer after forming the sensing electrodes.

5. The method as set forth in claim 1, wherein the barrier layer is made of a thermosetting resin or a photocurable resin.

6. The method as set forth in claim 1, further comprising, curing the barrier layer.

7. The method as set forth in claim 1, wherein electrode wirings are formed in the concave portions simultaneously with forming the sensing electrodes, the electrode wiring being made of a metal and connected to the sensing electrodes.

8. The method as set forth in claim 1, wherein the stamp is a flat type or a circular type.

9. The method as set forth in claim 1, wherein the sensing electrodes are formed so as to be embedded in the concave portions.
